(19) United States
(12) Patent Application Publication
(10) Pub. No.: US 2007/0029186 A1
(43) Pub. Date: Feb. 8, 2007

(54) Method of thermally tempering coated article with transparent conductive oxide (TCO) coating using inorganic protective layer during tempering and product made using same

(76) Inventors: Alexey Krasnov, Canton, MI (US); Yiwei Lu, Ann Arbor, MI (US); Philip J. Lingle, Temperance, MI (US)

Correspondence Address: NIXON & VANDERHYE, PC, 901 NORTH GLEBE ROAD, 11TH FLOOR, ARLINGTON, VA, 22203, US

(21) Appl. No.: 11/194,760

(22) Filed: Aug. 2, 2005

(51) Int. Cl. C23C 14/00

(52) U.S. Cl. 204/192.29

(57) ABSTRACT

A method of making a coated article including a transparent conductive oxide (TCO) film supported by a glass substrate is provided. In certain embodiments, the coated article including the TCO film on the glass substrate is thermally tempered in a tempering furnace with an inorganic protective film (e.g., of or including silicon nitride) being provided on the glass substrate over the TCO film during tempering in order to prevent or reduce oxidizing of the TCO during the tempering process. Since oxidizing of the TCO film during the tempering process is prevented or reduced, the TCO film is able to maintain its electrically conductivity, even after tempering.

This invention relates to a method of making a coated article including a transparent conductive oxide (TCO) film supported by a glass substrate. In certain example embodiments, the coated article including the TCO film on the glass substrate is thermally tempered in a tempering furnace. During tempering, an inorganic protective film (e.g., of or including silicon nitride) is provided on the glass substrate over the TCO film in order to prevent or reduce oxidizing of the TCO during the tempering process. Since oxidizing of the TCO film during the tempering process is prevented or reduced, the TCO film is able to maintain its electrical conductivity, even after tempering. A coated article, that is thermally tempered and made by such a process is also provided. Coated articles according to certain example non-limiting embodiments of this invention may be used in applications such as solar cells, oven doors, defrosting windows, or other types of windows in certain example instances.

### BACKGROUND AND SUMMARY OF EXAMPLE EMBODIMENTS OF INVENTION

Typically, methods of forming TCOs on glass substrates require high glass substrate temperatures. Such methods include chemical pyrolysis where precursors are sprayed onto the glass substrate at approximately 400 to 500 degrees C. and vacuum deposition where the glass substrate is kept at about 150 to 300 degrees C. Unfortunately, TCO films such as SnO₂:F formed on glass substrates by chemical pyrolysis suffer from non-uniformity and thus may be unpredictable and/or inconsistent with respect to certain optical and/or electrical properties.

Sputter deposition of a TCO at approximately room temperature would be desirable, given that most float glass manufacturing platforms are not equipped with in-situ heating systems. An additional potential advantage of sputter-deposited TCO films is that they may include the integration of anti-reflection coatings, resistivity reduction, and so forth.

There is often a need to thermally temper coated articles having a glass substrate coated with a TCO film/coating. For instance, in certain applications tempering is required by code (e.g., e.g., for windows over doorways, for windows identified as breakable windows for firemen, and other applications). Thermal tempering typically requires heating the glass substrate with a coating thereon in a tempering furnace at a temperature of at least about 580 degrees C., more preferably at least about 600 degrees C., and often at least about 620 or 640 degrees C. (e.g., for at least about 2 minutes, more preferably for at least about 5 minutes). Thus, it will be appreciated that thermal tempering involves very high temperatures.

Unfortunately, it has been found that glass substrates supporting sputter-deposited TCOs cannot be thermally tempered without the TCOs suffering a significant loss in electrical conductivity. Glass tempering temperatures (see above) cause a rapid conductivity drop in certain TCOs (e.g., sputter-deposited zinc oxide inclusive TCOs). It is believed that this drop in conductivity is due to oxidation of the TCO during the tempering process.

Thus, it will be appreciated that there exists a need in the art for an improved technique or method of tempering glass substrates including TCO films/coatings thereon, which can prevent or reduce oxidation of the TCO during tempering and thus allow the TCO to substantially maintain its electrical conductivity during and/or after the tempering process.

In certain example embodiments of this invention, a method is provided for thermally tempering a glass substrate with a TCO film/coating thereon. The thermal tempering typically involves heating the glass substrate with the TCO coating thereon in a tempering furnace at a temperature of at least about 580 degrees C., more preferably at least about 600 degrees C., and often at least about 620 or 640 degrees C. The glass substrate with the TCO coating thereon may be in the tempering furnace for at least about 2 minutes, more preferably for at least about 5 minutes, in certain example embodiments of this invention.

In certain example embodiments, an inorganic protective layer(s) is provided on the glass substrate over the TCO film so as to protect the TCO film from oxidation during the tempering process. The provision of the inorganic protective layer(s) prevents or reduces oxidation of the TCO during the tempering process. By reducing oxidation of the TCO during the tempering process, more of the electrical conductivity of the TCO coating can be maintained during and/or after tempering.

In certain example embodiments, the inorganic protective layer or film is a dielectric and comprises or consists essentially of a layer of or including silicon nitride. In certain example embodiments of this invention, the inorganic protective layer (e.g., silicon nitride) may be substantially free of oxygen. Thus, for example, in certain example embodiments, the silicon nitride protective layer contains no more than about 10% oxygen (atomic %), more preferably no more than about 5% oxygen, even more preferably no more than about 2% oxygen, and in some cases no oxygen. The lack of oxygen, or lack of substantial amounts of oxygen, in the inorganic protective film helps protect the TCO film from oxidizing during the tempering process and is advantageous for this reason.

In certain example embodiments of this invention, it is advantageous to substantially match the indices of refraction of the TCO film and the overlying inorganic protective layer. Thus, for example, zinc aluminum oxide (an example TCO in certain forms) and silicon nitride (an example inorganic protective layer) both have approximately the same indices of refraction (n) around 2.0. The substantial matching of indices (n) helps camouflage the protective layer from an optical perspective, so as to cut down on reflection or the like. In certain example embodiments of this invention, the respective indices of refraction (n) (at 450 nm) of the TCO film and the inorganic protective layer differ by no more than about 0.2, more preferably by no more than about 0.1.

In certain example embodiments of this invention, it is advantageous to substantially match the coefficients of thermal expansion of the TCO film and the overlying inorganic protective layer. Thus, for example, zinc aluminum oxide (an example TCO in certain forms) has a coefficient of thermal expansion of about 6×10⁻⁶ degrees K⁻¹ whereas silicon nitride (an example inorganic protective layer) has a coefficient of thermal expansion of about 3.3×10⁻⁶ degrees K⁻¹. The substantial matching of the respective coefficients of thermal expansion is advantageous with respect to durability, in that stress caused by thermal mismatches between the layers can be reduced; and delaminations and/or coating failures during or following tempering can also be reduced. In certain example embodiments of this invention, the coefficient of thermal expansion of the TCO film does not differ from that of the inorganic protective layer by more than about 10%, more preferably not by more than about 5%, and even more preferably by not more than about 1%.

In certain example embodiments of this invention, the TCO film may be sputter-deposited on a glass substrate (either directly or indirectly) at approximately room temperature. In alternative embodiments, it is possible to pre-heat the glass substrate prior to the sputter-deposition of the TCO film. Example sputter-deposited TCO films include films of or including ZnAlOₓ:Ag, ZnO, ITO (indium-tin-oxide), SnO₂ and/or SnO₂:F. Other types of TCO films may instead be used.

In certain example embodiments of this invention, there is provided a method of making a thermally tempered coated article including a transparent conductive film on a glass substrate, the method comprising: providing a glass substrate; sputter-depositing a transparent conductive film comprising a transparent conductive oxide on the glass substrate; sputter-depositing an inorganic protective layer comprising silicon nitride on the glass substrate directly over and contacting the transparent conductive film; and thermally tempering the coated article including the glass substrate, the transparent conductive film, and the protective layer comprising silicon nitride, wherein the protective layer comprising silicon nitride prevents or reduces oxidizing of the transparent conductive film during tempering thereby allowing the transparent conductive film to have electrically conductive properties following the tempering.

In other example embodiments of this invention, there is provided a method of making a thermally tempered coated article including a transparent conductive film on a glass substrate, the method comprising: providing a glass substrate; forming a transparent conductive film comprising a transparent conductive oxide on the glass substrate; forming an inorganic protective layer on the glass substrate over at least the transparent conductive film; and thermally tempering the coated article including the glass substrate, the transparent conductive film, and the protective layer.

In still further example embodiments of this invention, there is provided a thermally tempered coated article comprising: a thermally tempered glass substrate; a transparent conductive oxide film comprising zinc oxide and/or tin oxide provided on the tempered glass substrate; and an inorganic protective layer provided on the glass substrate over the transparent conductive oxide film.

### BRIEF DESCRIPTION OF THE DRAWINGS

FIG. 1 is a cross sectional view of a coated article according to an example embodiment of this invention.

FIG. 2 is a flowchart illustrating a method of making a thermally tempered coated article according to an example embodiment of this invention.

FIG. 3 is a cross sectional view of a coated article according to another example embodiment of this invention.

### DETAILED DESCRIPTION OF EXAMPLE EMBODIMENTS OF THE INVENTION

Coated articles including conductive layer(s) according to certain example non-limiting embodiments of this invention may be used in applications such as solar cells, oven doors, defrosting windows, display applications, or other types of windows in certain example instances. For example and without limitation, the transparent conductive layers discussed herein may be used as electrodes in solar cells, as heating layers in defrosting windows, as solar control layers in windows, electromagnetic radiation/wave shielding applications, and/or the like.

Sputter deposition of transparent conductive oxide (TCO) films has been of growing interest. For a number of products, temperable TCO-coated glass is required or desired. Commercially available temperable fluorine-doped tin oxide films produced by chemical pyrolysis suffer from non-uniformity. Additional potential advantages of sputtered films could also include the integration of anti-reflection coatings, resistivity reduction, and so forth.

An example sputter-deposited TCO film is of zinc oxide doped with aluminum (e.g., ZnAlOₓ). For such TCOs, they are substantially substoichiometric with respect to oxygen, thereby permitting them to be electrically conductive. Sputter-deposited zinc oxide doped with aluminum, deposited in a substoichiometric manner, results in a low-resistivity TCO film having high visible transmission. However, when it is subjected to tempering temperatures, the film rapidly loses its conductivity; it is believed that this loss of conductivity is due to oxidation of the TCO during tempering.

In certain example embodiments of this invention, a method is provided for thermally tempering a glass substrate with a TCO film/coating thereon. The thermal tempering typically involves heating the glass substrate with the TCO coating thereon in a tempering furnace at a temperature of at least about 580 degrees C., more preferably at least about 600 degrees C., and often at least about 620 or 640 degrees C. The glass substrate with the TCO coating thereon may be in the tempering furnace for at least about 2 minutes, more preferably for at least about 5 minutes, in certain example embodiments of this invention.

In certain example embodiments of this invention, an inorganic protective layer(s) is provided on the glass substrate over the TCO film so as to protect the TCO film from oxidation during the tempering process. The provision of the inorganic protective film prevents or reduces oxidation of the TCO during the tempering process. By reducing oxidation of the TCO during the tempering process, more of the electrical conductivity of the TCO coating can be maintained during and/or after tempering.

Electrical conductivity can be measured in terms of sheet resistance (Rₛ). The TCO's discussed herein have a sheet resistance (Rₛ) of no greater than about 200 ohms/square, more preferably no greater than about 100 ohms/square, and most preferably from about 5-100 ohms/square. The conductivity of a TCO film is often caused by depositing the film in a manner so that the film is substoichiometric with respect to oxygen. The oxygen substoichiometry causes oxygen vacancies which allow current to flow through the layer. As an example, stoichiometric zinc oxide (ZnO) is usually high resistive and thus dielectric in nature because of its wide bandgap; however, zinc oxide can be made conductive by creating nonidealities or point defects in its crystal structure to generate electrically active levels (e.g., by making it oxygen deficient which is substoichiometric with respect to oxygen) thereby causing its sheet resistance to drop significantly into the range discussed above. This can be done by using an oxygen deficient atmosphere during crystal growth and/or by doping.

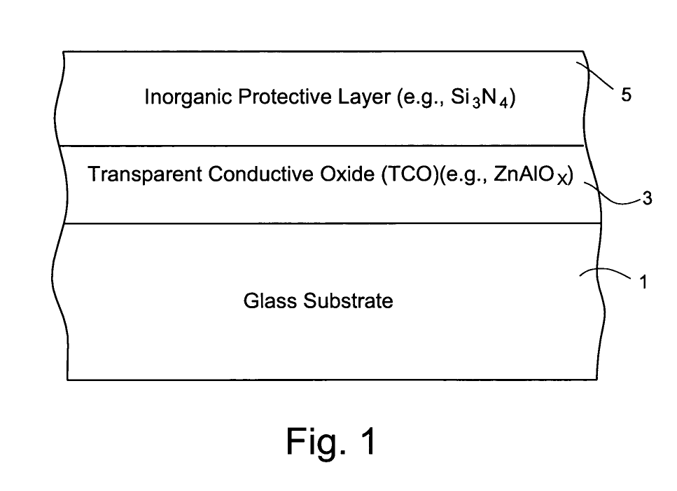

FIG. 1 is a cross sectional view of a coated article, before and/or after tempering, according to an example embodiment of this invention. The coated article includes glass substrate 1, TCO film or layer 3 provided on the glass substrate, and inorganic protective layer 5 provided on the glass substrate over at least the TCO film 3. Glass 1 may be soda-lime-silica glass in certain example embodiments of this invention, although other types of glass may instead be used. In certain embodiments, TCO layer/coating 3 may be made up of one or more layers and is provided directly on and contacting the top surface of glass substrate 1. However, in other example embodiments of this invention, other layer(s) (not shown) may be provided between the glass substrate 1 and the transparent conductive layer 3. Layer 3 is said to be “on” and “supported” by/on the substrate 1, regardless of whether other layer(s) are provided therebetween. In certain example embodiments of this invention, the coated article has a visible transmission of at least about 30%, more preferably of at least about 50%, and even more preferably of at least about 70%.

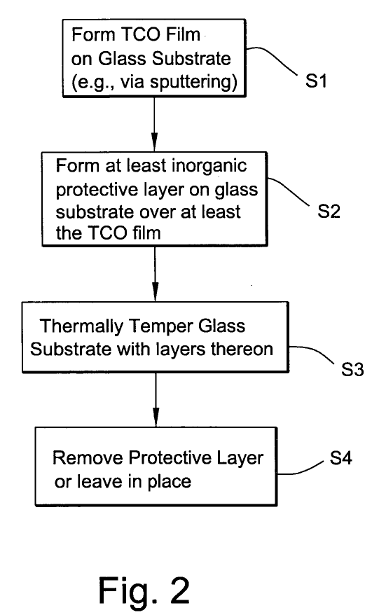

FIG. 2 is a flowchart illustrating certain steps carried out in making a thermally tempered coating article according to an example embodiment of this invention. Initially, a film or coating 3 of or including a transparent conductive oxide (TCO) is formed or deposited on a glass substrate 1 (step S1 in FIG. 2; see also film 3 on glass substrate 1 in FIG. 1). The TCO film 3 may be deposited by sputtering in certain example embodiments of this invention; e.g., sputtering a magnetron target(s) at approximately room temperature. In alternative embodiments, it is possible to pre-heat the glass substrate prior to the sputter-deposition of the TCO film 3. For example and without limitation, example TCO films 3 include films of or including ZnAlOₓ:Ag, ZnAlOₓ, ZnO, ITO, SnZnOₓ, SnO₂ and/or SnO₂:F. The TCO film 3 may be a single layer of a TCO, or alternatively may be a multi-layer stack, an alloyed compound, or their combination in different example embodiments of this invention. In certain example instances, the use of SnZnOₓ as the TCO film 3 may be advantageous to better tailor the electrical and/or optical properties of the film, e.g., to improve layer etchability for display applications, enhance carrier mobility and/or transmission, and so forth.

Following deposition of the TCO film 3 on the glass substrate 1, at least one inorganic protective layer 5 is formed on the glass substrate over at least the TCO film 3 (see step S2 in FIG. 2; and FIG. 1). In certain example embodiments of this invention, the protective film 5 may be formed directly on and contacting the TCO film 3, although it is possible for other layer(s) to be provided therebetween in alternative embodiments. The protective layer 5 is formed by sputter-deposition in certain example embodiments of this invention (e.g., sputtering a Si or SiAl target in a gaseous atmosphere including a mixture of Ar and N gases to form a silicon nitride based or inclusive protective layer 5).

For example and without limitation, an example inorganic protective layer 5 is of or includes silicon nitride (e.g., Si₃N₄, or other suitable stoichiometry). In certain example embodiments of this invention, the inorganic protective layer 5 (e.g., of or including silicon nitride) may be substantially free of oxygen. Thus, for example, in certain example embodiments, the silicon nitride protective layer 5 contains no more than about 10% oxygen (atomic %), more preferably no more than about 5% oxygen, even more preferably no more than about 2% oxygen, and in some cases no oxygen. The lack of oxygen, or lack of substantial amounts of oxygen, in the inorganic protective layer 5 helps protect the TCO film 3 from oxidizing during the tempering process and is advantageous for at least this reason.

In certain example embodiments of this invention, it is advantageous to substantially match the indices of refraction of the TCO film 3 and the overlying inorganic protective layer 5. Thus, for example, in certain example embodiments of this invention zinc aluminum oxide (an example TCO in certain substoichiometric forms) and silicon nitride (an example inorganic protective film) both have approximately the same indices of refraction (n) around 2.0. The substantial matching of indices (n) helps camouflage the protective layer 5 from an optical perspective, so as to cut down on reflection or the like. In certain example embodiments of this invention, the respective indices of refraction (n) (at about 555 nm) of the TCO film 3 and the inorganic protective layer 5 differ by no more than about 0.2, more preferably by no more than about 0.1.

In certain example embodiments of this invention, it is advantageous to substantially match the coefficients of thermal expansion of the TCO film 3 and the overlying inorganic protective layer 5. Thus, for example, zinc aluminum oxide (an example TCO in certain substoichiometric forms) has a coefficient of thermal expansion of about 6×10⁻⁶ degrees K⁻¹ whereas silicon nitride (an example inorganic protective layer) has a coefficient of thermal expansion of about 3.3×10⁻⁶ degrees K⁻¹. The substantial matching of the respective coefficients of thermal expansion is advantageous with respect to mechanical durability, in that stress caused by thermal mismatches between the layers can be reduced; and delaminations and/or coating failures during or following tempering can also be reduced. In certain example embodiments of this invention, the coefficient of thermal expansion of the TCO film 3 does not differ from that of the inorganic protective layer 5 by more than about 10%, more preferably not by more than about 5%, and even more preferably by not more than about 1%. While the protective layer 5 is preferably of or includes silicon nitride in a dielectric form in certain example embodiments of this invention, it is possible to use other materials as the protective layer 5.

After the TCO film 3 and the protective layer 5 have been formed on the glass substrate 1, the coated article including the TCO film 3 and protective layer 5 on the glass substrate 1 enters a thermal tempering furnace for tempering (step S3 in FIG. 2). The thermal tempering typically involves heating the glass substrate 1 with the TCO coating 3 thereon in the tempering furnace at a temperature of at least about 580 degrees C., more preferably at least about 600 degrees C., and often at least about 620 or 640 degrees C. The glass substrate 1 with the TCO film 3 and protective layer 5 thereon may be in the tempering furnace for at least about 2 minutes, more preferably for at least about 5 minutes, in certain example embodiments of this invention. During tempering, the protective layer(s) 5 protects the TCO film 3 from substantial oxidizing. By reducing oxidation of the TCO film 3 during the tempering process, more of the electrical conductivity of the TCO coating can be maintained during and/or after tempering.

After the glass substrate 1 with the TCO film 3 and protective layer 5 thereon exits the tempering furnace, the glass is permitted to cool in a known manner thereby resulting in the thermal tempering thereof. Thus, a thermally tempered glass substrate 1 has been provided with a TCO film 3 and a protective layer 5 thereon. The tempered coated article may then be used in monolithic window applications, oven door applications, IG window unit applications, solar cells, heatable window applications, or the like. The TCO may function as a heatable layer/coating (when voltage is applied thereacross) in certain applications such as heatable window applications, or alternatively may function as a heat or IR blocking layer/coating in applications such as oven doors, or alternatively may function as an electrode in applications such as solar cell applications.

Following tempering, it is possible to leave the protective layer 5 in place on the substrate (see step S4 in FIG. 2). Thus, the final coated article would include each of 3 and 5 on the glass substrate. However, in alternative embodiments, it is possible to remove the layer 5 from the substrate following the tempering process, thereby exposing the TCO film 3 to atmosphere (e.g., in certain example electrode applications).

For purposes of example and without limitation, an example of sputter-depositing a TCO film 3 on a glass substrate will now be described. In certain example embodiments of this invention, TCO inclusive film 3 is sputter-deposited onto substrate 1 at a low temperature (e.g., less than about 150 degrees C., more preferably less than about 100 degrees C., and possibly at approximately room temperature) so as to include both a primary dopant and a co-dopant. For purposes of example, the film 3 may be zinc oxide based, the primary dopant may be Al, and the optional co-dopant may be Ag. In such an example situation, the TCO film 3 may be of or include ZnAlOₓ:Ag, where Ag is the co-dopant. Al is the primary charge carrier dopant. However, if too much Al is added (without Ag), its effectiveness as a charge carrier is compromised because the system compensates Al by generating native acceptor defects (such as zinc vacancies). Also, at low substrate temperatures, more clustered electrically inactive (yet optically absorbing) defects tend to occur. However, when Ag is added as a co-dopant, this promotes declustering of the Al and permits more Al to function as a charge generating dopant (Al is more effective when in the Zn substituting sites). Thus, the use of the Ag permits the Al to be a more effective charge generating dopant in the TCO inclusive film 3. Accordingly, the use of Ag in ZnAlO is used to enhance the electrical properties of the film. In certain example embodiments of this invention, the amount of primary dopant (e.g., Al) in the film 3 may be from about 0.5 to 7%, more preferably from about 0.5 to 5%, and most preferably from about 1 to 4% (atomic %). Moreover, in certain example embodiments of this invention, the amount of co-dopant (e.g., Ag) in the film 3 may be from about 0.001 to 3%, more preferably from about 0.01 to 1%, and most preferably from about 0.02 to 0.25% (atomic %). In certain example instances, there is more primary dopant in the film than co-dopant, and preferably there is at least twice as much primary dopant in the film than co-dopant (more preferably at least three times as much, and most preferably at least 10 times as much). Moreover, there is significantly more Zn and 0 in the film 3 than both Al and Ag, as the film 3 may be zinc oxide based—various different stoichiometries may be used for film 3. The use of both the primary dopant (e.g., Al) and the co-dopant (e.g., Ag) in depositing (e.g., sputter-depositing) the TCO inclusive film (e.g., ZnAlOₓ:Ag) 3 prevents or reduces the formation of compensating native defects in a wide-bandgap semiconductor material during the impurity introduction by controlling the Fermi level at or proximate the edge of the growth. Immediately after being captured by surface forces, atoms start to migrate and follow the charge neutrality principle. The Fermi level is lowered at the growth edge by the addition of a small amount of acceptor impurity (such as Ag) so it prevents the formation of the compensating (negative in this case) species, such as zinc vacancies. After the initial stage of the semiconductor layer formation, the mobility of atoms is reduced and the probability of the point defect formation is primarily determined by the respective energy gain. Silver atoms in this particular case tend to occupy interstitial sites where they play role of predominantly neutral centers, forcing Al atoms to the preferable zinc substitutional sites, where Al plays the desired role of shallow donors, thus eventually raising the Fermi level. In addition, the provision of the co-dopant (Ag) promotes declustering of the primary dopant (Al), thereby freeing up space in the metal sublattice of the film 3 and permitting more primary dopant (Al) to function as a charge provider so as to improve conductivity of the film. Accordingly, the use of the co-dopant (Ag) permits the primary dopant (Al) to be more effective in enhancing conductivity of the TCO inclusive film 3, without significantly sacrificing visible transmission characteristics. Furthermore, the use of the co-dopant surprisingly improves crystallinity of the TCO inclusive film 3 and thus the conductivity thereof, and grain size of the crystalline film 3 may also increase which can lead to increased mobility. While silver is discussed as a co-dopant in certain example embodiments of this invention, it is possible to use another Group IB, IA or V element such as Cu or Au instead of or in addition to silver as the co-dopant in TCO film 3. Moreover, while Al is discussed as a primary dopant in certain example embodiments of this invention, it is possible to use another material such as Mn (instead of or in addition to Ag) as the primary dopant for the TCO film 3.

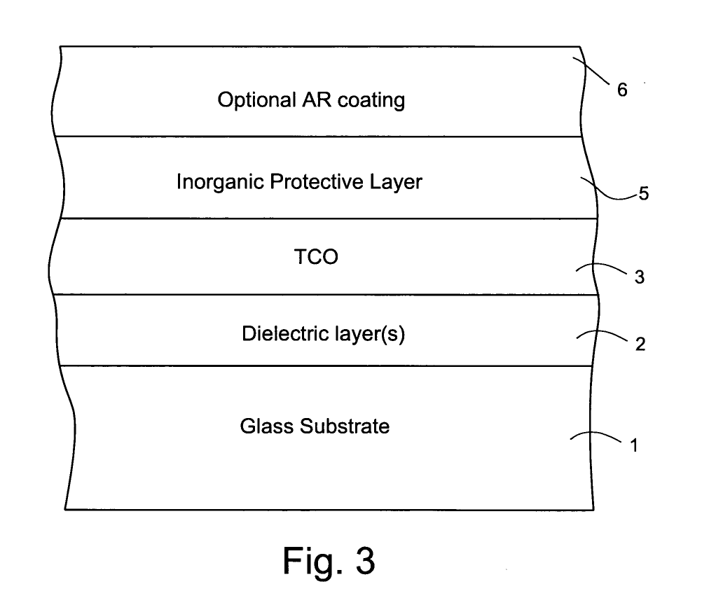

FIG. 3 is a cross sectional view of a coated article according to another example embodiment of this invention. The FIG. 3 embodiment is the same as the FIG. 1-2 embodiment discussed above, except that additional dielectric layer(s) 2 and optional antireflective (AR) coating 6 are provided on the substrate. Dielectric layer 2 may be of or include a material such as aluminum oxide for blocking sodium migration from the glass substrate 1 during tempering, thereby protecting the TCO layer from experiencing a loss in conductivity. Thus, dielectric layer 2 is advantageous in this respect. In certain example embodiments, aluminum oxide of layer 2 can form aluminosilicate in layer 2 due to sodium migration from the glass during tempering, thereby permitting the layer 2 to act as a rather dense barrier against sodium migration. Other possible materials for dielectric layer 2 include silicon nitride and/or silicon oxynitride. Dielectric layer 2 is typically deposited by sputtering at approximately room temperature. Optional AR coating 6 may be made up of one or more layers and is provided for anti-reflection purposes. AR coating 6 (e.g., of or including SiO₂) is preferably a dielectric coating in certain example embodiments of this invention.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

For example, in certain example embodiments a mechanically matching layer(s) or layer stack may be provided between the TCO film 3 and the inorganic protective layer 5 to reduce stress caused by thermal mismatch between the dissimilar layers during tempering. Moreover, in certain example embodiments an optically matching layer(s) or layer stack may be provided between the TCO film 3 and the inorganic protective layer 5. Furthermore, in certain example embodiments, an anti-reflection coating may be provided on top of the protective layer 5 in the form of a single layer or a multi-layer stack for temperable products. In still further example embodiments, the protective layer 5 may be an integral part of an anti-reflection coating system provided on the substrate over the TCO film 3.

1. A method of making a thermally tempered coated article including a transparent conductive film on a glass substrate, the method comprising:
providing a glass substrate;
sputter-depositing a transparent conductive film comprising a transparent conductive oxide on the glass substrate;
sputter-depositing an inorganic protective layer comprising silicon nitride on the glass substrate directly over and contacting the transparent conductive film; and
thermally tempering the coated article including the glass substrate, the transparent conductive film, and the protective layer comprising silicon nitride, wherein the protective layer comprising silicon nitride prevents or reduces oxidizing of the transparent conductive film during tempering thereby allowing the transparent conductive film to have electrically conductive properties following the tempering.

2. The method of claim 1, wherein the inorganic protective layer contains no more than about 10% oxygen, and wherein the transparent conductive film has a sheet resistance (Rₛ) of from about 5 to 100 ohms/square.

3. The method of claim 1, wherein the inorganic protective layer contains no more than about 5% oxygen.

4. The method of claim 1, wherein the inorganic protective layer contains no more than about 2% oxygen.

5. The method of claim 1, wherein the inorganic protective layer contains no oxygen.

6. The method of claim 1, wherein another layer is provided on the glass substrate so as to be located between the glass substrate and the transparent conductive film.

7. The method of claim 1, wherein the coated article has a visible transmission of at least about 50% before and/or after the tempering.

8. The method of claim 1, wherein the transparent conductive film comprises ZnAlOₓ, and is substoichiometric with respect to oxygen.

9. The method of claim 1, wherein the transparent conductive film comprises zinc oxide and/or tin oxide, and is substoichiometric with respect to oxygen.

10. The method of claim 1, wherein respective indices of refraction (n) of the transparent conductive film and the protective layer differ by no more than about 0.2.

11. The method of claim 1, wherein respective indices of refraction (n) of the transparent conductive film and the protective layer differ by no more than about 0.1.

12. The method of claim 1, wherein respective coefficients of thermal expansion of the transparent conductive film and the protective layer do not differ by more than about 10%.

13. The method of claim 1, wherein respective coefficients of thermal expansion of the transparent conductive film and the protective layer do not differ by more than about 1%.

14. A method of making a thermally tempered coated article including a transparent conductive film on a glass substrate, the method comprising:
providing a glass substrate;
forming a transparent conductive film comprising a transparent conductive oxide on the glass substrate;
forming an inorganic protective layer on the glass substrate over at least the transparent conductive film; and
thermally tempering the coated article including the glass substrate, the transparent conductive film, and the protective layer.

15. The method of claim 14, wherein the inorganic protective layer contains no more than about 10% oxygen.

16. The method of claim 14, wherein the inorganic protective layer contains no more than about 5% oxygen.

17. The method of claim 14, wherein the inorganic protective layer contains no more than about 2% oxygen.

18. The method of claim 14, wherein the coated article has a visible transmission of at least about 50% before and/or after the tempering.

19. The method of claim 14, wherein respective indices of refraction (n) of the transparent conductive film and the protective layer differ by no more than about 0.2.

20. The method of claim 14, wherein respective coefficients of thermal expansion of the transparent conductive film and the protective layer do not differ by more than about 1%.

21. A thermally tempered coated article comprising:
a thermally tempered glass substrate;
a transparent conductive oxide film comprising zinc oxide and/or tin oxide provided on the tempered glass substrate; and
an inorganic protective layer provided on the glass substrate over the transparent conductive oxide film.
